(19) United States
(12) Patent Application Publication
(10) Pub. No.: US 2010/0078671 A1
(43) Pub. Date: Apr. 1, 2010

(54) Nitride based semiconductor light emitting device

(76) Inventors: Kuo-Chin HUANG, Lung Tan (TW); Shyi-Ming Pan, Lung Tan (TW); Hung-Li Pan, Lung Tan (TW); Cheng-Kuo Huang, Lung Tan (TW); Wei-Kang Cheng, Lung Tan (TW); Yi-Sheng Ting, Lung Tan (TW)

Correspondence Address: SINORICA, LLC, 2275 Research Blvd., Suite 500, ROCKVILLE, MD, 20850, US

(21) Appl. No.: 12/354,820

(22) Filed: Jan. 16, 2009

(30) Foreign Application Priority Data
Oct. 1, 2008 (TW) 097137795

(51) Int. Cl. H01L 33/00

(52) U.S. Cl. 257/103; 257/E33.013

(57) ABSTRACT

A nitride based semiconductor light emitting device is revealed. The light emitting device includes a light emitting epitaxial layer, a P-type electrode and a N-type electrode. The P-type electrode and the N-type electrode are disposed on the light emitting epitaxial layer. The light emitting device features on that the N-type electrode is arranged on the inner side of the P-type electrode. The P-type electrode extends toward the N-type electrode along the edge of the light emitting epitaxial layer and the N-type electrode extends inward along the inner side of the P-type electrode. By means of the electrode pattern with special design, the light emitting area of the light emitting device is increased.

### BACKGROUND OF THE INVENTION

1. Field of the invention

The present invention relates to a light emitting device, especially to a nitride based semiconductor light emitting device.

2. Description of Related Art

Light emitting diode (LED) is a light emitting element made of semiconductor material. The light source includes two electrodes. After being applied with voltage (minimum current), the electron-hole recombination process produces some photons due to energy gap of electrons and electron-holes. Thus the LED emits light. The LED is different from a general Incandescent bulb and it's a cold illuminant with features of low power consumption, long lifetime, no idle time, and fast reaction. Moreover, the LED has compact volume, good shock resistance, and suitableness for mass production. Thus the LED is easily to be produced in the form mini-type or array-type element according to users' requirements. It has been applied to electrical appliances, computers and communication products and has become one of the essentials in our daily lives.

In order to increase light emitting area of the LED, now special electrode pattern is designed to achieve this purpose. As to conventional LED, the p-type electrode covers most of the area of the p-type semiconductor layer and this leads to poor light emitting efficiency of the LED.

In order to solve above problem, there is a need to provide a nitride based semiconductor light emitting device with larger light emitting area through special design of electrode patterns so as to improve light emitting efficiency of the LED.

### SUMMARY OF THE INVENTION

Therefore it is a primary object of the present invention to provide a nitride based semiconductor light emitting device in which a N-type electrode is disposed inside a P-type electrode and the N-type electrode is with smaller area so as to increase light emitting area of the light emitting device.

In order to achieve above object, the present invention provides a nitride based semiconductor light emitting device that includes a light emitting epitaxial layer, a P-type electrode and a N-type electrode. The P-type electrode and the N-type electrode are disposed on the light emitting epitaxial layer while the N-type electrode is located on an inner side of the P-type electrode. The P-type electrode extends toward the N-type electrode along an edge of the light emitting epitaxial layer and the N-type electrode extends inward along the inner side of the P-type electrode.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing showing a top view of an embodiment according to the present invention;

FIG. 2 is a cross sectional view of the embodiment in FIG. 1;

FIG. 3 is another cross sectional view of the embodiment in FIG. 1;

FIG. 4 is a schematic drawing showing a cross sectional view of another embodiment according to the present invention;

FIG. 5 is a schematic drawing showing a cross sectional view of a further embodiment according to the present invention.

### DETAILED DESCRIPTION OF THE PREFERRED EMBODIMENT

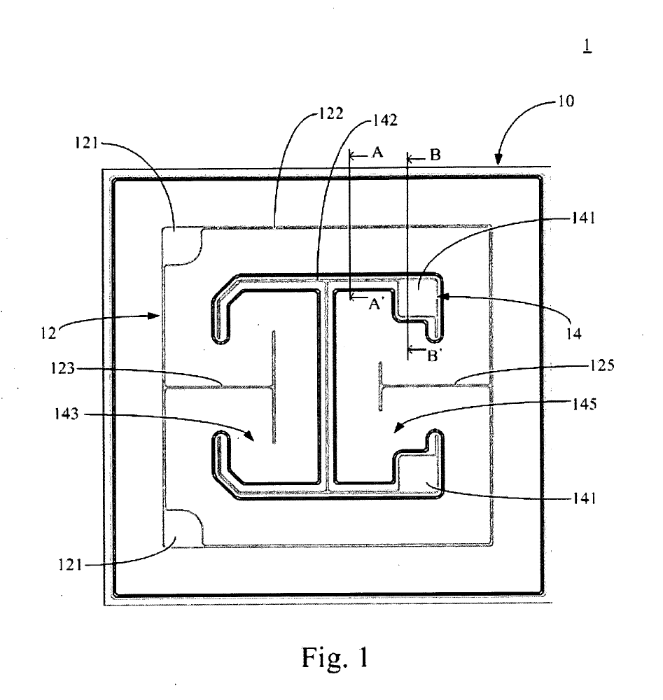

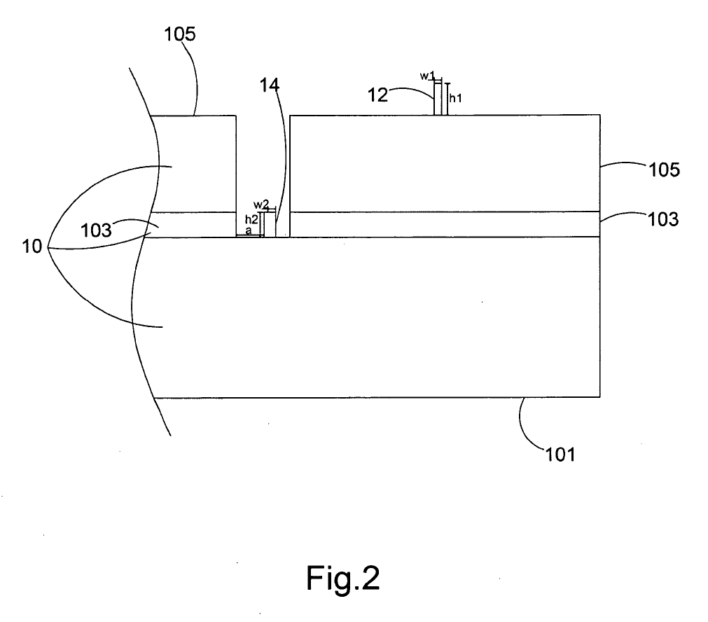

Refer to FIG. 1 & FIG. 2, a front view and a partial cross sectional view of an embodiment of a nitride based semiconductor light emitting device according to the present invention are disclosed. The FIG. 2 is a cross sectional view of the embodiment in FIG. 1 along A-A′ line. The light emitting device 1 includes a light emitting epitaxial layer 10, a P-type electrode 12 and a N-type electrode 14. The light emitting epitaxial layer 10 consists of a N-type semiconductor layer 101, a light emitting layer 103 and a P-type semiconductor layer 105. The light emitting layer 103 is disposed over the N-type semiconductor layer 101 and the P-type semiconductor layer 105 is arranged over the light emitting layer 103. The P-type electrode 12 is set on one side of the P-type semiconductor layer 105, opposite to the light emitting layer 103. The N-type electrode 14 is arranged on the N-type semiconductor layer 101 and is located on one side of the light emitting layer 103 as well as one side of the N-type semiconductor layer 101.

Refer to FIG. 1, the P-type electrode 12 includes two projecting member 121 that are arranged symmetrically and are extending toward the N-type electrode 14 along an edge of the light emitting epitaxial layer 10 to form a strip-like member 122. The P-type electrode 12 in this embodiment is a closed loop and the N-type electrode 14 is disposed on an inner side of the P-type electrode 12. As to the N-type electrode 14, it also includes two projecting members 141 that are symmetrically arranged and are extending along the P-type electrode 12 to form a strip-like member 142. The N-type electrode 14 comprises a first section 143 and a second section 145. The second section 145 is located on one side of the first section 143. The P-type electrode 12 includes a first branch 123 and a second branch 125. The first branch 123 extends into the first section 143 of the N-type electrode 14 while the second branch 125 extends into the second section 145 of the N-type electrode 14.

Refer to the FIG. 2, the ratio of the width (w1) of a cross section of the P-type electrode 12 to the height (h1) of the cross section thereof ranges from 0.3 to 10 while the optimal ratio of the width (w1) to the height (h1) of the cross section of the P-type electrode 12 is from 0.5 to 5. The ratio of the width (w2) of a cross section of the N-type electrode 14 to the height (h2) of the cross section thereof ranges 0.3 to 10 and the preferred ratio of the width (w2) to the height (h2) of the cross section of the N-type electrode 14 is from 0.5 to 5. The cross sectional area of the P-type electrode 12 is larger than that of the N-type electrode 14.

Back to FIG. 1, the perimeter of the P-type electrode 12 is longer than that of the N-type electrode 14 while the total area of the P-type electrode 12 with the area of the N-type electrode 14 is smaller than 15 percent of the area of the light emitting epitaxial layer 10. The distance between an outer edge of the P-type electrode 12 and the edge of the light emitting epitaxial layer 10 ranges from 2 μm to 300 μm while the optimal distance is from 50 μm to 150 μm. The distance between an outer edge of the P-type electrode 12 and the edge of the light emitting epitaxial layer 10 is not larger than the distance between an inner edge of the P-type electrode 12 and an outer edge of the N-type electrode 14. The distance between the inner edge of the P-type electrode 12 and the outer edge of the N-type electrode 14 is not a fixed value. The electrode pattern satisfying above conditions can effectively increase light emitting area of the light emitting device 1. The electrode pattern shown here is only one of the embodiments according to the present invention.

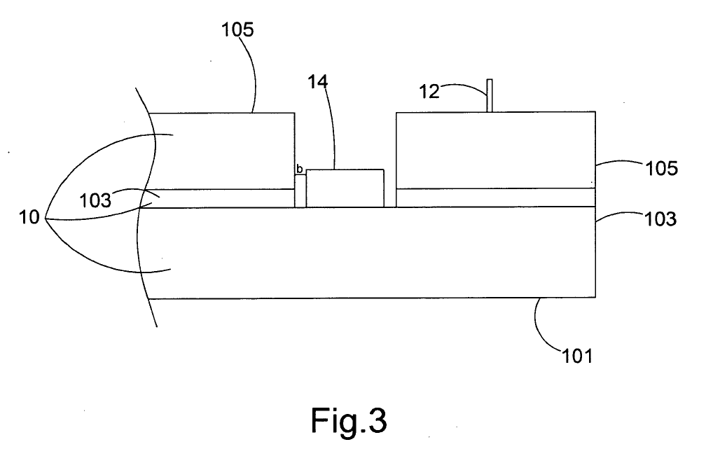

Refer to FIG. 3, another cross sectional view of the embodiment in FIG. 1 along B-B′ line is disclosed. The distance between one side of the projecting member 141 of N-type electrode 14, near the P-type semiconductor layer 105 as well as the light emitting layer 103, and the P-type semiconductor layer 105 ranges from 0.1 μm to 100 μm while the optimal distance therebetween is smaller than 100 μm. In this embodiment, the distance between one side of the projecting member 141 of N-type electrode 14 that is near the P-type semiconductor layer 105 as well as the light emitting layer 103, and the P-type semiconductor layer 105 is larger than the distance between one side of the strip-like member 142 of the N-type electrode 14 near the P-type semiconductor layer 105 as well as the light emitting layer 103, and the P-type semiconductor layer 105 so as to prevent misalignment of wires.

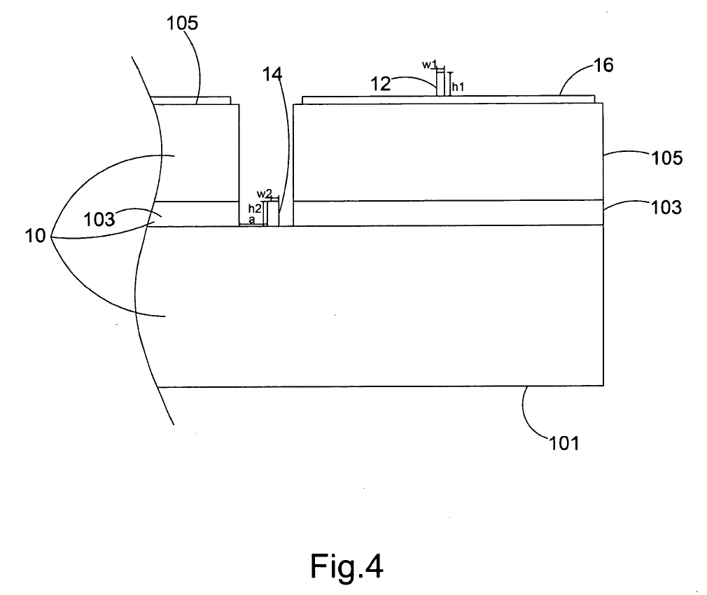

Refer to FIG. 4, another embodiment of the present invention is disclosed. As shown in figure, the light emitting device 1 similar to the embodiment in FIG. 2 includes the light emitting epitaxial layer 10, the P-type electrode 12 and the N-type electrode 14. The light emitting epitaxial layer 10 consists of the N-type semiconductor layer 101, the light emitting layer 103 and the P-type semiconductor layer 105. The light emitting layer 103 is disposed over the N-type semiconductor layer 101 and the P-type semiconductor layer 105 is arranged over the light emitting layer 103. The P-type electrode 12 is set on the P-type semiconductor layer 105 and the N-type electrode 14 is arranged on the N-type semiconductor layer 101 and is located on one side of the light emitting layer 103 as well as the N-type semiconductor layer 101. The light emitting device 1 in this embodiment further includes a transparent conductive layer 16 between the P-type electrode 12 and the P-type semiconductor layer 105.

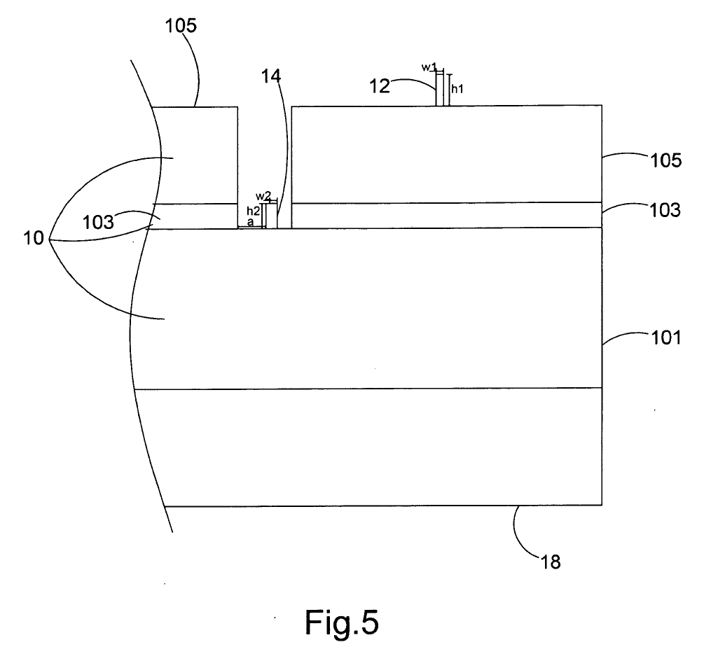

Refer to FIG. 5, a cross sectional view of a further embodiment is disclosed. As shown in figure, the light emitting device 1 similar to the one in FIG. 2 comprises the light emitting epitaxial layer 10, the P-type electrode 12 and the N-type electrode 14. The P-type electrode 12 and the N-type electrode 14 are disposed on the light emitting epitaxial layer 10. The light emitting device 1 in this embodiment further includes a substrate 18 on one side thereof opposite to the P-type electrode 12 as well as the N-type electrode 14.

In summary, a nitride based semiconductor light emitting device according to the present invention features on that the N-type electrode is disposed on the inner side of the P-type electrode and the P-type electrode extends toward the N-type electrode along the edge of the light emitting epitaxial layer and the N-type electrode extends inward along the inner side of the P-type electrode. Due to the N-type electrode with smaller area and disposed on the inner side of the P-type electrode, the light emitting area of the device is increased.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A nitride based semiconductor light emitting device comprising:
a light emitting epitaxial layer,
a P-type electrode disposed on the light emitting epitaxial layer; and
a N-type electrode arranged on the light emitting epitaxial layer and located on an inner side of the P-type electrode;
wherein the P-type electrode extends toward the a N-type electrode along an edge of the light emitting epitaxial layer and the N-type electrode extends inward along an edge of an inner side of the P-type electrode.

2. The device as claimed in claim 1, wherein the light emitting epitaxial layer comprising:
a N-type semiconductor layer,
a light emitting layer disposed over the N-type semiconductor layer; and
a P-type semiconductor layer arranged over the light emitting layer;
wherein the P-type electrode is disposed on the P-type semiconductor layer, opposite to the light emitting layer and the N-type electrode is arranged on the N-type semiconductor layer.

3. The device as claimed in claim 1, wherein area of the P-type electrode is larger than area of the N-type electrode.

4. The device as claimed in claim 1, wherein perimeter of the P-type electrode is longer than perimeter of the N-type electrode.

5. The device as claimed in claim 1, wherein area of the P-type electrode together with area of the N-type electrode is smaller than 15 percent of area of the light emitting epitaxial layer.

6. The device as claimed in claim 1, wherein distance between an edge on an outer side of the P-type electrode and an edge of the light emitting epitaxial layer ranges from 2 μm to 300 μm.

7. The device as claimed in claim 6, wherein the optimal distance between an edge on an outer side of the P-type electrode and an edge of the light emitting epitaxial layer ranges from 50 μm to 150 μm.

8. The device as claimed in claim 1, wherein distance between an edge on an outer side of the P-type electrode and an edge of the light emitting epitaxial layer is not larger than distance between an edge on an inner side of the the P-type electrode and an edge on an outer side of the N-type electrode.

9. The device as claimed in claim 1, wherein the device further comprising:
a substrate arranged on the light emitting epitaxial layer and opposite to the P-type electrode as well as the N-type electrode.

10. The device as claimed in claim 1, wherein the P-type electrode is a closed loop.

11. A nitride based semiconductor light emitting device comprising:
a light emitting epitaxial layer;
a P-type electrode disposed on the light emitting epitaxial layer; and
a N-type electrode arranged on the light emitting epitaxial layer and located on an inner side of the P-type electrode and the N-type electrode having at least one strip-like member and at least one projecting member;
wherein distance between one side of the strip-like member of the N-type electrode near the light emitting epitaxial layer and the light emitting epitaxial layer is smaller than distance between one side of the projecting member 141 of N-type electrode near the light emitting epitaxial layer and the light emitting epitaxial layer.

12. A nitride based semiconductor light emitting device comprising:
a light emitting epitaxial layer;
a P-type electrode disposed on the light emitting epitaxial layer; and
a N-type electrode arranged on the light emitting epitaxial layer and located on an inner side of the P-type electrode;
wherein ratio of width of the P-type electrode to height of the P-type electrode ranges from 0.3 to 10.

13. The device as claimed in claim 12, wherein ratio of width of the N-type electrode to height of the N-type electrode ranges from 0.3 to 10.

14. The device as claimed in claim 12, wherein the optimal ratio of width of the P-type electrode to height of the P-type electrode ranges from 0.5 to 5.

15. The device as claimed in claim 13, wherein the optimal ratio of width of the N-type electrode to height of the N-type electrode ranges from 0.5 to 5.

16. The device as claimed in claim 12, wherein area of the P-type electrode is larger than area of the N-type electrode.

17. The device as claimed in claim 12, wherein distance between an edge on an outer side of the P-type electrode and an edge of the light emitting epitaxial layer ranges from 2 μm to 300 μm.

18. The device as claimed in claim 17, wherein the optimal distance between an edge on an outer side of the P-type electrode and an edge of the light emitting epitaxial layer ranges from 50 μm to 150 μm.

19. The device as claimed in claim 12, wherein distance between an edge on an outer side of the P-type electrode and an edge of the light emitting epitaxial layer is not larger than distance between an edge on an inner side of the the P-type electrode and an edge on an outer side of the N-type electrode.

20. The device as claimed in claim 12, wherein the P-type electrode is a closed loop.
